(19) United States
(12) Patent Application Publication
(10) Pub. No.: US 2013/0118553 A1
(43) Pub. Date: May 16, 2013

(54) WAFER-BASED SOLAR CELL

(71) Applicant: Swinburne University of Technology, Hawthorn VIC (AU)

(72) Inventors: Min Gu, Doncaster (AU); Baohua Jia, Mont Albert North (AU); Narges Fahim, Endeavour Hills (AU); Zi Ouyang, Hawthorn East (AU)

(73) Assignee: SWINBURNE UNIVERSITY OF TECHNOLOGY, Hawthorn VIC (AU)

(21) Appl. No.: 13/677,456

(22) Filed: Nov. 15, 2012

(30) Foreign Application Priority Data
Nov. 15, 2011 (AU) 2011904770

(51) Int. Cl. H01L 31/0216; H01L 31/18

(52) U.S. Cl. CPC H01L 31/02168; H01L 31/18
USPC 136/246; 136/256; 438/71

(57) ABSTRACT

A solar cell product including:
a bulk semiconductor substrate having one or more solar cells formed therein; and
nanoscale particles distributed over a surface of the solar cells to scatter sunlight forward into the solar cells and thereby enhance the efficiency of the solar cells.

### RELATED APPLICATIONS

This specification is associated with Australian Provisional Patent Application No. 2011904770, the originally filed specification of which is hereby incorporated herein by reference.

### FIELD

The present invention relates to solar cells with bulk semiconductor substrates, e.g., including plasmonic nanoparticles.

### BACKGROUND

Wafer-based silicon solar cells, which include bulk semiconductor substrates, are widely used in the global solar market; however, there is an ongoing need to increase their light conversion efficiency at a low cost, e.g., to make photovoltaic (PV) solar energy competitive with other energy sources.

There is also a need to enhance the efficiency of multicrystalline (mc) solar cells without overly increasing manufacturing costs.

It is desired to address or ameliorate one or more disadvantages or limitations associated with the prior art, or to at least provide a useful alternative.

### SUMMARY

In accordance with the present invention, there is provided a solar cell product including:

a bulk semiconductor substrate having one or more solar cells formed therein; and

nanoscale particles distributed over a surface of the solar cells to scatter sunlight forward into the solar cells and thereby enhance the efficiency of the solar cells.

The present invention also provides a method of manufacturing a solar cell including:

receiving a bulk semiconductor substrate having solar cells formed therein; and

depositing nanoscale particles on a surface of the solar cells to scatter light forward into the solar cells.

The present invention also provides a solar cell including nanoparticles, synthesised using a wet chemical method, on a front surface of the cell.

In embodiments, the particles can be deposited from a suspension of the particles, or from reduction of ions in solution.

In embodiments, the particles can have diameters ranging from about 10 nanometres (nm) to about 100 nm.

In embodiments, the particles can be spherical.

In embodiments, the solar cell can include a multicrystalline or a monocrystalline wafer in a photovoltaic (PV) apparatus.

In embodiments, the particles can be deposited with a surface coverage density of about 0.5% to about 10%.

In embodiments, the solar cell can include:

conductive fingers or conductors for conducting electricity generated from the sunlight; and

conductive coatings deposited from the solution on the conductive fingers or conductors for conducting the electricity.

In embodiments, the method can include the step of depositing conductive coatings on conductive fingers on the solar cell.

In embodiments, the method can include the step of depositing the particles by electroless deposition from an ionic solution.

In embodiments, the method can include the step of depositing the particles by dipping the solar cell into a suspension of the particles.

### BRIEF DESCRIPTION OF THE DRAWINGS

Preferred embodiments of the present invention are hereinafter further described, by way of example only, with reference to the accompanying drawings, in which:

FIG. 1A is a schematic diagram of an electroless coated solar cell;

FIG. 1B is a schematic diagram of a dip-coated solar cell;

FIG. 1C-1F are schematic diagrams of steps in the dip-coating method;

FIG. 1G is a photograph of an example apparatus for the dip-coating method;

FIG. 2A is a flow chart of a method of electroless deposition on the solar cell;

FIG. 2B is a flow chart of a method of dip coating the solar cell;

FIGS. 2C(a)-2C(c) are scanning electron microscope (SEM) micrographs for silver (Ag) nanoparticles deposited by electroless coating on a front surface of example planar silicon solar cells; and their corresponding histograms showing statistical analysis of the size distributions of diameters of: (a) 21.4 nm; (b) 52.5 nm; and (c) 110 nm with surface coverage of 3%, 2.94% and 11% respectively;

FIG. 3(a) a graph of reflectance (as a percentage) as a function of wavelength (in nanometres) of a “pristine” example solar cell (without nanoparticles), and example cells with silver nanoparticles of average sizes 21 nm, 52.5 nm and 110 nm;

FIG. 3(b) is a graph relative reflectance (normalised to an uncoated cell) the cells in FIG. 3(a);

FIG. 4 is a graph of the J-V characteristics of the cells in FIG. 3(a);

FIG. 5(a) is a graph of Equivalent Quantum Efficiency (EQE), as a percentage, of the cells in FIG. 3(a);

FIG. 5(b) is a graph of relative EQE of the cells in FIG. 3(a));

FIG. 6 is a graph of relative EQE and relative reflectance (normalised to an uncoated cell) of example planar silicon solar cells with silver nanoparticles of average size 110 nm;

FIG. 7(a) is an SEM micrograph of an example conductive finger (of the solar cell) plated with a conductive coating by electroless deposition; and the inset is a schematic diagram of the conductive coating (a nano-shell) formed over the finger;

FIG. 7(b) is an SEM micrograph of the finger shown in FIG. 7(a) before deposition of the coating; and the inset is a schematic diagram of the finger in FIG. 7(a) before deposition of the coating;

FIGS. 8(a)-8(f) are SEM micrographs for example gold colloidal nanoparticles (NPs) of 61 nm, 107 nm, and 146 nm diameter at different magnifications;

FIGS. 8(g)-8(i) are transmission electron microscopy (TEM) images of the NPs of FIG. 8(a)-8(c) respectively;

FIGS. 8(j)-8(1) are histograms of particle size distributions for the particles sizes of FIGS. 8(a)-8(c) respectively;

FIG. 9(a) is a graph of UV-visible absorption spectra of example gold colloidal nanoparticles suspended in an aqueous solution with the following diameters: (x) 61 nm, (y) 107 nm, and (z) 146 nm; and the inset is a photograph of synthesised solutions of the nano NPs in FIG. 9(a);

FIG. 9(b) is a graph of the wavelengths (in nm) of surface plasmon resonance peaks (SPR, λₘₐₓ) for example NPs with different particle diameters (in nm);

FIG. 10 is a graph of a spectrum of gold NPs deposited on an example silicon substrate with a gold peak;

FIGS. 11(a) and (b) are SEM micrographs of Au NPs, with diameters 61 nm and 107 nm respectively, deposited on a top surface of example multicrystalline silicon (Si) solar cells;

FIG. 12 (a) is a graph of reflectance (as a %) of example multicrystalline Si solar cells before integration with NPs;

FIG. 12(b) is a graph of a reflectance ratio as a function of wavelength (in nm) for example multicrystalline solar cells with integrated gold NPs of diameters 61 nm, 107 nm, 146 nm normalised to the reflectance in FIG. 12(a);

FIG. 13(a) is a graph of the EQE (as a percent) as a function of wavelength (in nm) for an example solar cell prior to integration with NPs;

FIG. 13(b) is a graph of the EQE ratio as a function of wavelength (in nm) of the solar cells integrated with Au NPs of diameters 61 nm, 107 nm and 146 nm respectively, normalised to the EQE in FIG. 13(a); and

FIG. 14 is a graph of a J-V characteristic curve for an example solar cell before and after integration of Au NPs with a diameter of 61 nm.

### DETAILED DESCRIPTION

### Overview

Recently, plasmonic nanostructures have been proposed for improving conversion efficiency of thin film solar cells; however, these proposal have related only to enhancing light trapping (which is related to photocurrent) in optically thin film solar cells rather than in wafer-based solar cells.

Embodiments of the present invention provide a wafer-based (i.e., optically thick monocrystalline or multicrystalline) solar cell with particles (which are also referred to as nanoparticles, or NPs) deposited from a solution onto a surface of the cell; however, embodiments may be particularly useful for multicrystalline solar cells because effective texturing is difficult to achieve due to their random grain orientations. For multicrystalline solar cells, which do not absorb well near the band-edge, plasmonic enhanced light-trapping in the long wavelength region can be particularly beneficial.

The particles are configured to scatter sunlight forward into the cell. Before the deposition, the solar cell can be a commercially available solar cell manufactured using commercially available techniques.

To improve energy conversion efficiency in solar cells, the following fundamental aspects can be improved: photocurrent generation, charge carrier transportation, and current collection. These aspects can be represented by the following parameters in solar cells: short-circuit current (J_{sc}), open-circuit voltage (V_{oc}), and fill factor (FF). Almost all previous plasmonic solar cell proposal relate to photocurrent (J_{sc}) enhancement in optically thin solar cells (rather than enhancement in the FF and/or the V_{oc}).

Embodiments provide an enhancement in photocurrent and fill factor through depositing the particles on the front surface of the solar cells by modified versions of the following simple, industry-friendly and high-throughput methods:

(i) electroless deposition from an ionic solution; or

(ii) dip-coating the solar cell by dipping it into a suspension of the particles.

Embodiments can concurrently achieve enhancement in current generation (J_{sc}) and current collection (FF) by depositing particles (e.g., nanoparticles) on the front surface of solar cells (e.g., screen-printed silicon solar cells) by using the modified electroless deposition method or the modified dip-coating method. The particles can have controlled sizes and a controlled coverage density on the front surface (e.g., on the anti-reflection coating layer) to enable broadband sunlight trapping in the photovoltaic (PV) apparatus of the solar cell.

The control of the particle size may be important because small particles show strong absorption and little scattering, hence reducing the amount of light transmitted into the solar cells. On the other hand, large particles have a strongly red-shifted resonance, resulting in a reduced transmittance in the shorter-wavelength range due to the Fano effect. Therefore, properly designed metal NPs can strongly scatter NIR while maintaining minimum reduction in the visible range for high performance silicon solar cells. In order to enhance light-trapping in silicon solar cells, NPs can be selected to exhibit low absorption and large scattering cross-sections in the wavelength range of 300-1200 nm. NP absorption can be minimized by avoiding smaller particles. Since the enhancement of light absorption and hence the efficiency of light scattered into the active layer depends strongly on the particle size, Ag or Au NPs with different mean diameters in the range 50-200 nm (e.g., 61, 107 and 146 nm) can be used.

The metal nanoparticles (e.g., formed using silver, gold or aluminium, etc) can induce forward scattering, which increases the path length in the silicon active layer.

An increase in EQE indicates that the metal nanoparticles can strongly enhance the absorption in the photoactive layer and hence lead to the increase in the photocurrent.

The light is scattered by the dipolar resonance of the nanoparticle, which redirects the light preferentially into the higher refractive index solar cells. At longer wavelengths (λ>750 nm), a decrease of EQE can be due to an increase in back scattering.

In embodiments, simultaneous FF enhancement is provided by a highly conductive coating or shell (e.g., of Ag) on the fingers and busbar of the solar cell, thus reducing the series resistance and improving the current collection efficiency of the solar cell. The electroless deposition results in the formation of an metal shell connecting gaps between the metal particles in the fingers (e.g., formed by the screen printing process). The resistivity of the plated metal contacts can be much lower than that of the screen-printed metal contacts because pure metal is deposited during the electroless plating, rather than metal pastes containing organic binder and glass frit.

Embodiments can improve commercially available multicrystalline silicon solar cells, which generally exhibit lower efficiency than their counterpart single or monocrystalline silicon solar cells due to loss mechanisms such as optical, resistive and recombination losses.

Embodiments can improve light-trapping in the near-infrared (NIR), which is difficult to achieve with conventional surface texturing approaches, since the feature size of the texturing is preferable comparable to the wavelength of interest in order to scatter light effectively, and light trapping should be maximized for spectral regions where Si is poorly absorbing (near the band edge of Si).

Solution-based methods to produce NPs can be preferable to the physical methods because the solution-based methods can be used to synthesize uniform NPs with controlled particle size, whereas the synthesis of uniform-sized nanoparticles and their size control is very difficult to achieve by the physical methods. To use metal NPs for solar cell applications, the cost and efficiency of the fabrication method become a significant issue. The colloidal chemical synthesis can be a cheaper option with more precise control over the size, shape and coverage of the NPs.

### Electroless Cell

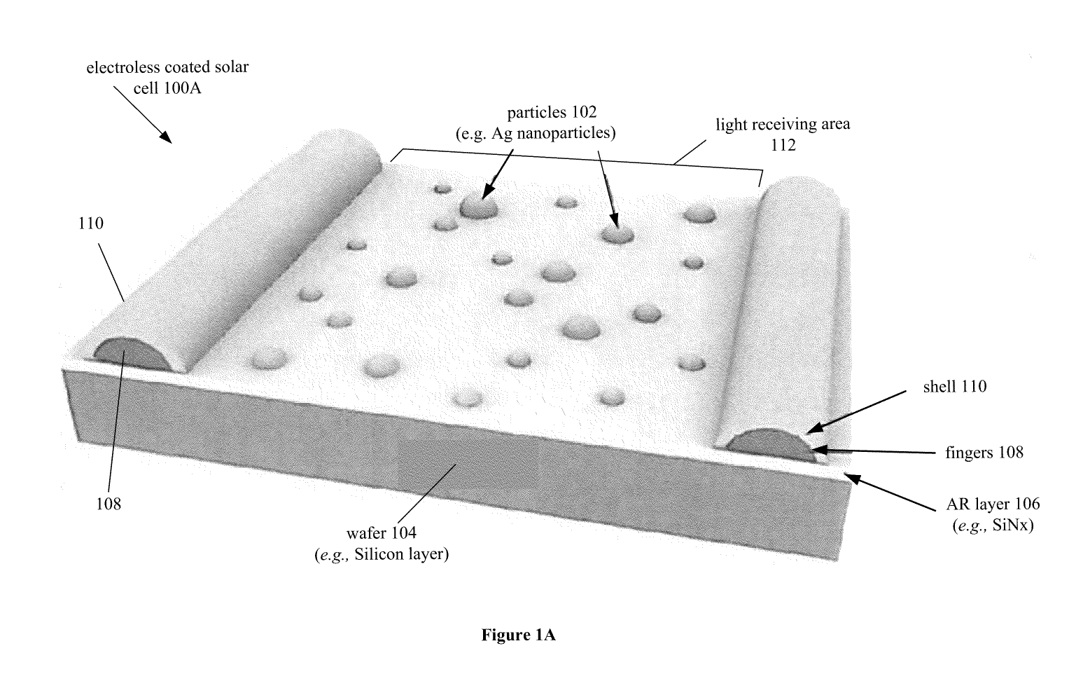

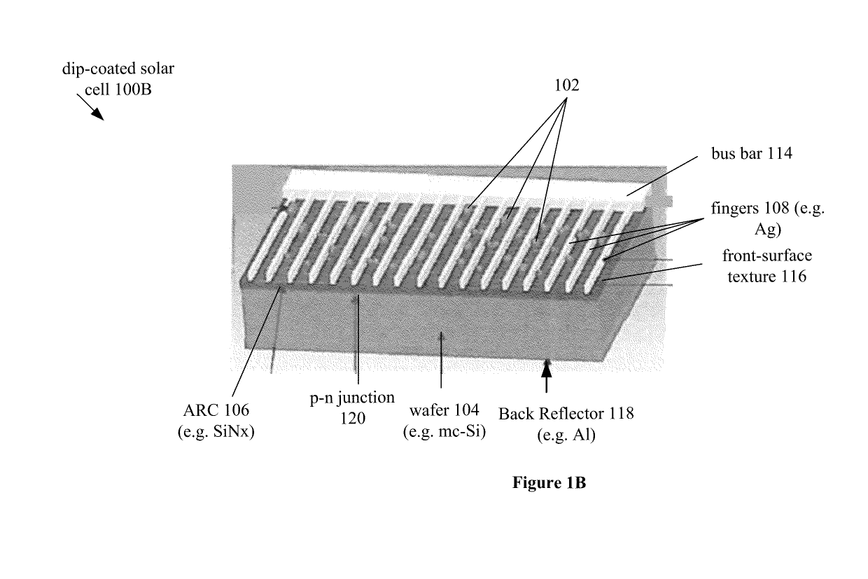

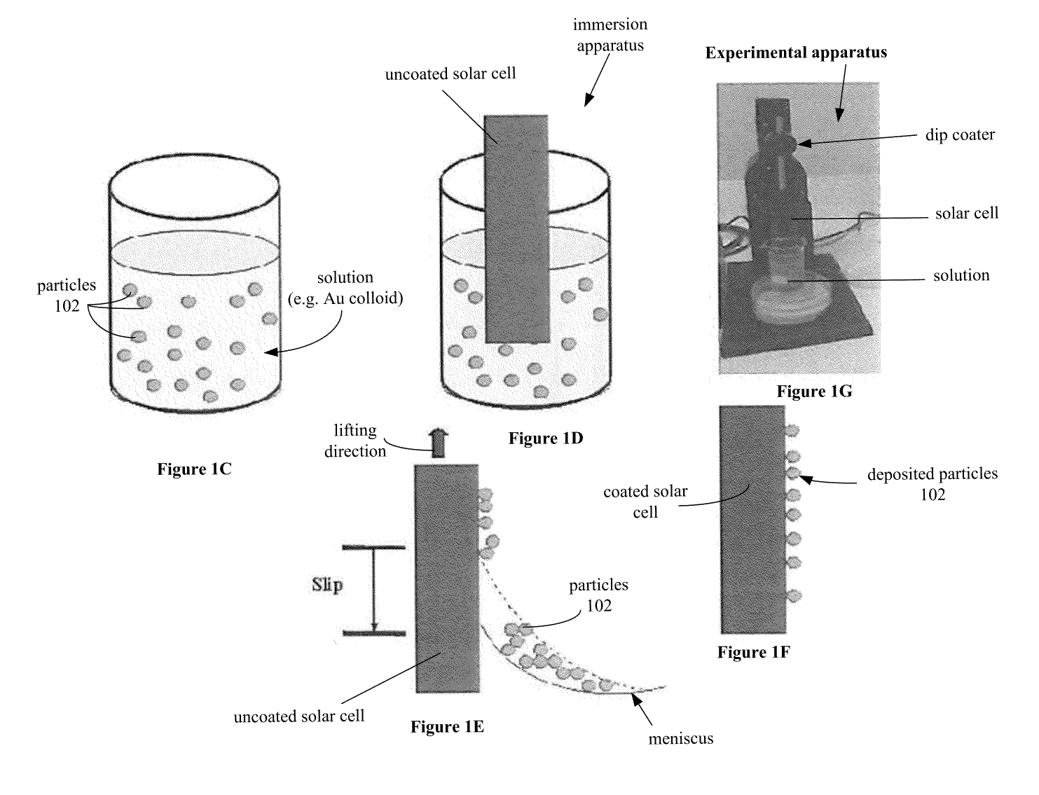

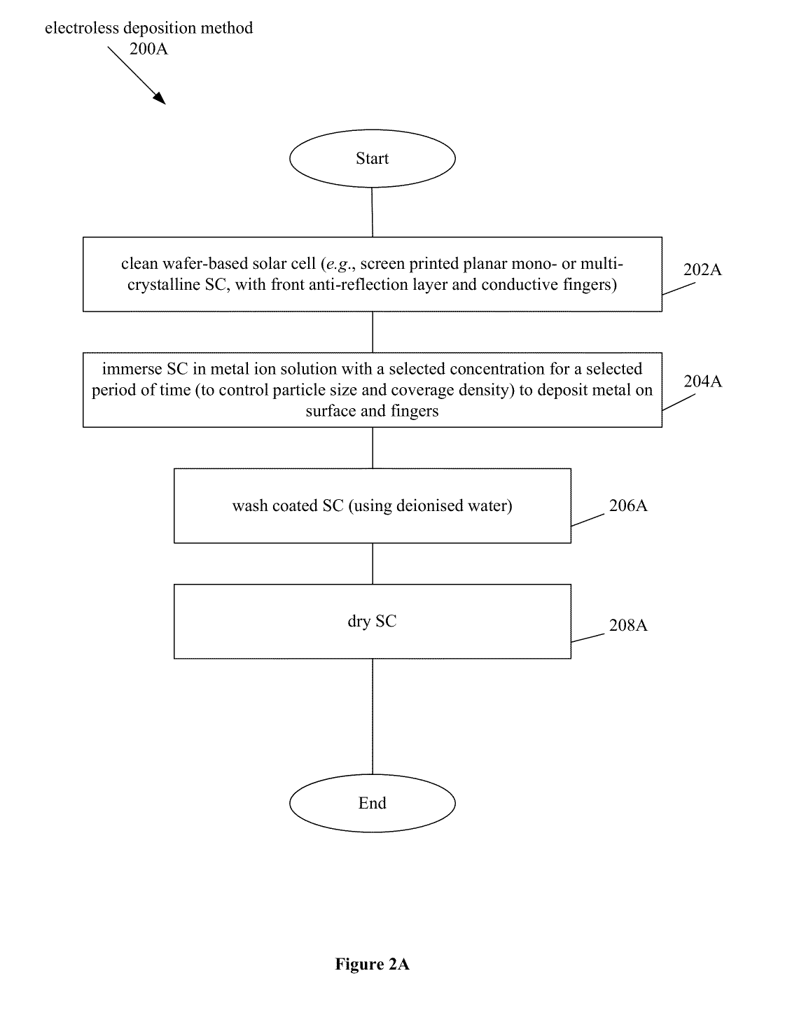

An electroless coated solar cell 100A, as shown in FIG. 1A, includes particles 102 deposited on a front surface (which is the sunlight-receiving surface) of the solar cell 100A. The electroless cell 100A includes a wafer 104 (e.g., a silicon layer) with an anti-reflective (AR) coating or layer 106 (e.g., formed from SiNx) on the front. In front of the AR layer 106 (or simply in the front of the waver 104 if no AR coating is present), the electroless cell 100A includes a plurality of conductive fingers 108 to carry electricity generated by the sunlight in the solar cell 100A.

The particles 102 are deposited on a light-receiving area 112 of the cell 100A (i.e., between the fingers 108). The particles 102 have controlled sizes and a coverage density selected to enhance light trapping in the cell 100A.

A conductive coating in the form of a shell 110 (which is also referred to as a nanoshell) is also deposited on the fingers 108. The shell 110 and the particles 102 can be deposited simultaneously. The shell 110 provides improves on the conductivity of the fingers 108, thus reducing losses in the cell 100A

The electroless method can provide both: (a) improved broadband light trapping (due to the particles 102); and (b) a reduction in series resistance (due to the shell 110). The electroless method can provide simultaneous improvement of the photocurrent generation and current collection in optically thick solar cells by concurrently using the particles 102 and the shells 110 produced through a single deposition step.

### Dip-Coated Cell

A dip-coated solar cell 100B, as shown in FIG. 1B, includes particles 102 deposited on a front surface (which is the sunlight-receiving surface) of the solar cell 100B. The dip-coated cell 100B includes the wafer 104 (e.g., a silicon layer) with the AR layer 106 (e.g., formed from SiNx) on the front. In front of the AR layer 106 (or simply in the front of the waver 104 if no AR coating is present), the dip-coated cell 100B includes a plurality of conductive fingers 108 to carry electricity generated by the sunlight in the solar cell 100B.

The particles 102 are deposited on light-receiving areas 112 of the cell 100B (i.e., between the fingers 108). The particles 102 have controlled sizes and a coverage density selected to enhance light trapping in the cell 100B.

As shown in FIG. 1B, the cell 100B (and the cell 100A) can include:

a bus bar 114 connected to the fingers 108 for conducting electricity from the fingers 108;

front-surface texture 116 at the front of the AR layer 106;

a back reflector 118 behind the wafer 104 for reflecting any sunlight that passes through the wafer 104 back into the wafer 104; and

a p-n junction that provides a part of the photovoltaic (PV) apparatus of the cell 100B (and the cell 100A).

Through integration of tailored NPs into wafer-based solar cells, light absorption in the active layer 104, and consequently photocurrent as well as external quantum efficiency (EQE), can be improved at longer wavelengths, while maintaining an almost unchanged photocurrent below the plasmon resonance wavelength. The enhancements can be due to the enhanced light trapping by the NPs 102 in the photoactive layer. Embodiments can be made with commercially available textured multicrystalline Si solar cells.

The reduction in the EQE response at the shorter wavelengths can be due to the phase shift, and the resulting destructive interference between the scattered light by the NPs and the light directly transmitted across the solar cell surface, specifically at wavelengths below the surface plasmon resonance of the NPs. For longer wavelengths above the plasmon resonance, the EQE can be significantly enhanced by the incorporation of the NPs of a selected in diameter (e.g., 61 nm in the dip-coated experimental example below) due to light trapping provided by the scattering of light by the dipolar resonance of the particles, which redirects the light preferentially forward into the solar cells. The photocurrent can be increased for sunlight with wavelengths from about 800 nm to about 1200 nm; however, for maximum enhancement in solar cell performance, it may be necessary to balance between the photocurrent enhancements at the long wavelengths and the photocurrent suppression at the short wavelengths when tailoring the NP size.

### Electroless Method

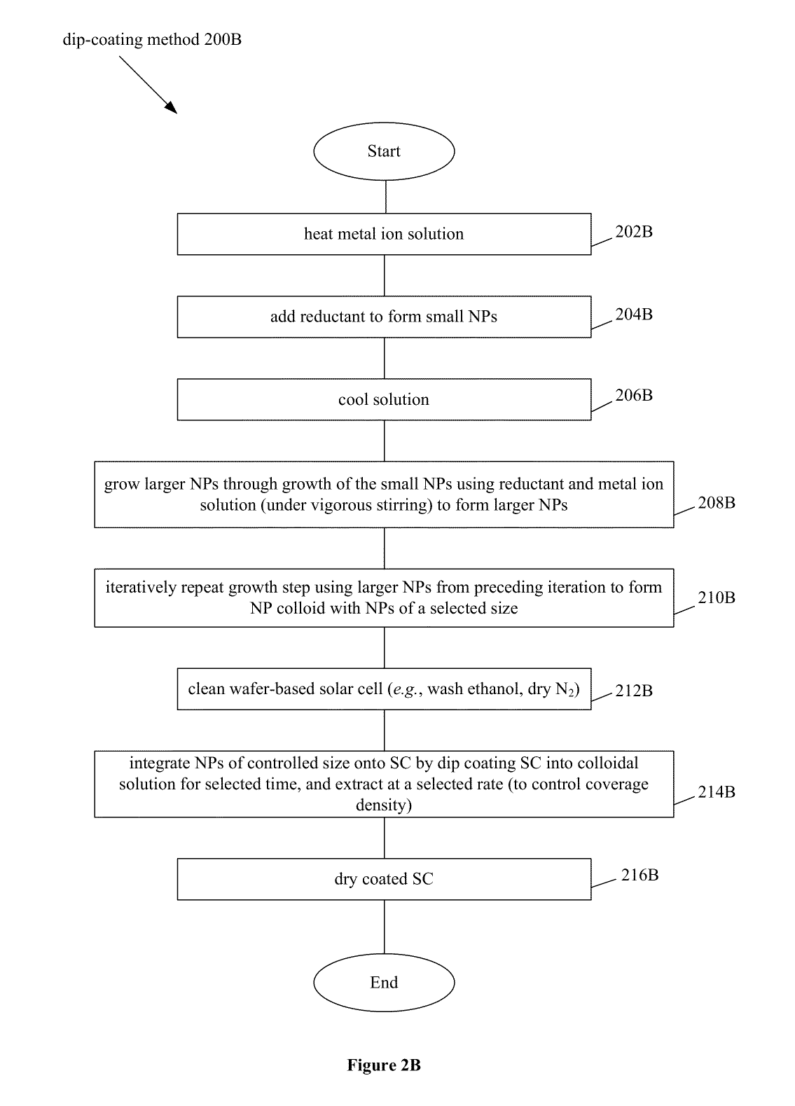

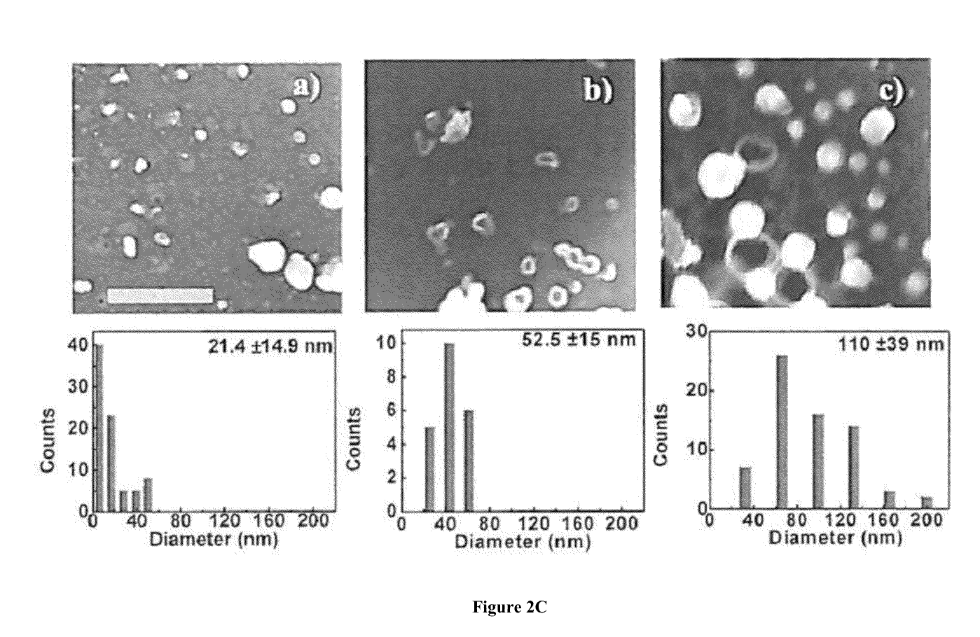

The electroless cell 100A is prepared in an electroless deposition method 200A, which includes the following steps, as shown in FIG. 2A:

cleaning the raw cell (step 202A);

immersing the raw cell in a metal ion solution (which is also referred to as a bath) with a selected concentration for a selected period of time (both selected to control the particle size, the shell thickness and the coverage density) to deposit the particles 102 onto the cell 100A (step 204A);

washing the coated cell 100A (step 206A); and

drying the washed cell 100A (step 208A).

The raw solar cell can be a commercially available textured mono- or multicrystalline Si solar cell.

The NPs 102 can be formed of a noble metal (e.g., Ag or Au) and spherically or spheroidally shaped.

The photocurrent can be increased for sunlight with wavelengths from about 800 nm to about 1200 nm.

The electroless deposition method 200A can be simple, cost effective and scalable for large-area device fabrication. Metal nanoparticles 102 prepared by this method 200A can exhibit excellent adhesion to the underlying substrate and their morphology can be tuned by controlling the electroless reaction conditions (including the metal ion bath concentration, immersion time and bath temperature).

The metallic nanoparticles 102 can be deposited directly on a passivation layer of the raw cell (e.g., the SiN_{X} dielectric layer) based on the presence of Si nanoclusters embedded in the passivation layer, where the anodic oxidation of Si is coupled to the cathodic reduction of metal ions (e.g., Ag⁺). The anodic dissolution of one atom of silicon yields four electrons leading to the direct deposition of four atoms of metal on the surface of the raw cell in a ratio of four silver atoms per one oxidised silicon atom. This method is able to produce nanoparticles with wide size distributions, which can enable broadband light trapping (since the plasmonic frequency of each NP is controlled by its size).

Electroless deposition can result in a distribution of particle diameters because the metal phase formation is a continuous process (i.e., new nanoparticles are formed while the old particles increase in diameter).

The electroless deposition method 200A can also form the thick shell layer 110 on the metal fingers 108.

In embodiments, the electroless deposition method 200A can use hydrofluoric (HF) acid, or less hazardous nitric acid (HNO₃).

### Dip-Coating Method

The dip-coated cell 100B is prepared in a dip-coating method 200B, which includes the following steps, as shown in FIGS. 1C-1F and 2B:
heating the metal ion solution (including a noble metal precursor, e.g., HAuCl₄ or AgNO₃) having a selected concentration (step 202B);
adding a reductant (e.g., NaBH₄) to the ion solution to form small NPs (step 204B);
cooling the solution of small NPs (step 206B);
growing larger NPs through deposition of additional metallic material on the small NPs by seeding a solution of reductant and the metal ions with the small NPs (step 208B);
growing increasingly larger NPs by iteratively repeating the growing step 208B using the already-grown NPs to seed the solution, until the NPs achieve a selected size (step 210B);
cleaning the cell 100B, e.g., with ethanol and nitrogen gas (step 212B);
integrating the iteratively grown NPs by dip-coating the raw solar cell into a colloidal suspension of the NPs having a selected concentration, for a selected period of time, and withdrawing the coated cell 100B at a selected rate, the selections being made to control the coverage density of the particles 102 on the cell 100B (step 214B); and
drying the coated cell 100B (step 216B).

The raw solar cell can be a commercially available textured mono- or multicrystalline Si solar cell.

The NPs 102 can be formed of a noble metal (e.g., Ag or Au) and spherically or spheroidally shaped. The NP diameter can be from about 50 nm to about 300 nm (e.g., 61 nm to 146 nm) in size. In embodiments, the preferred diameter is about 50 to 70 nm, or about 61 nm.

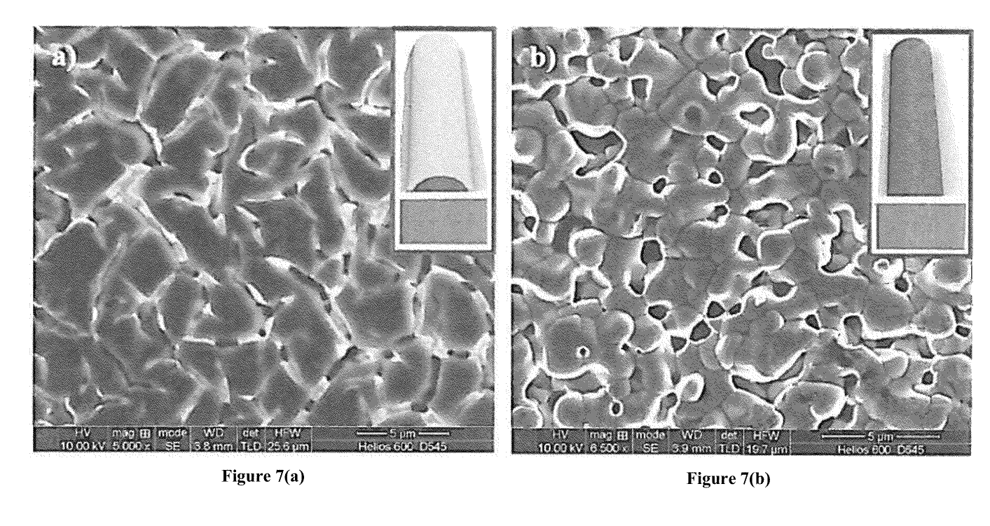

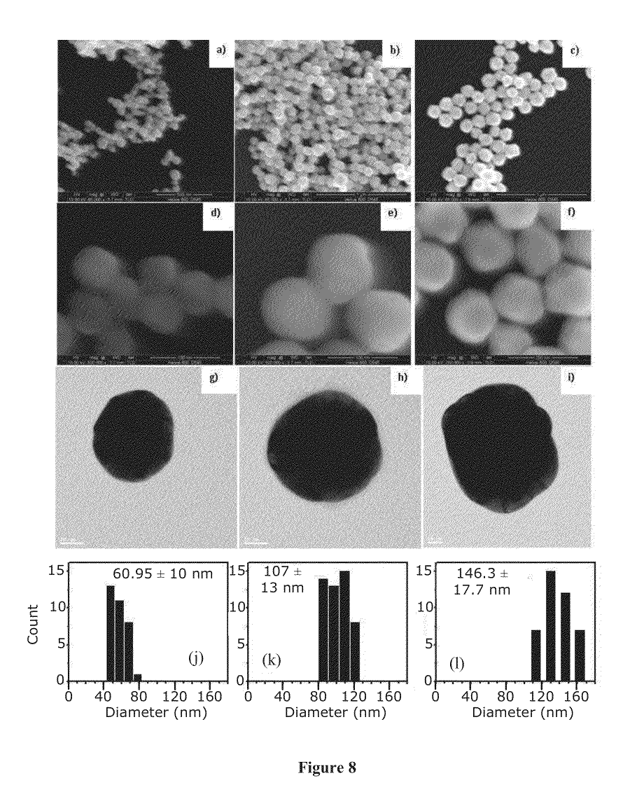

The iterative seeding process can be used to produce Au NPs of larger sizes ranging from about 20 to 150 nm with substantial monodisperisty (which is also referred to as uniformity) of spherical particles, without containing rod-shaped by-products, as shown in FIGS. 8(a) to 8(i). The lack of rod-shaped by-products narrows the bandwidth of the plasmonic response for photovoltaic applications.

In the dip-coating step 214B, the raw solar cells can be dipped into the colloidal metal solution and pulled out at a constant velocity, and then held in a holder until dried.

Selecting the dipping conditions, including the pulling speed, immersion time and solution concentration can allow control of the particle density.

The dip coating method can be fast, controllable and easy for integration of NPs into solar cells. Moreover, the particle layer can be formed with high throughput without wasting particles in the suspension.

### Electroless Experimental Example

In an experimental example, using the electroless method 200A, the randomly distributed tailored particles 102 on the surface provided broadband light trapping from 430 to 743 nm inside the silicon photoactive layer, which was well matched with the peak of the solar spectrum. A photocurrent enhancement of 4.03% was demonstrated due to the plasmonic enhanced light scattering.

Due to the formation of the highly conductive shell coatings on the fingers, the series resistance of the solar cells was dramatically reduced, leading to an enhancement of the FF (56.41 to 76.03%) and simultaneously an enhancement of the J_{sc}(31.05 to 32.3 mA/cm²). Thus up to a 35.23% relative enhancement in energy conversion efficiency (η) from the raw commercially available optically thick mono-crystalline silicon solar cells was measured.

The example screen-printed planar monocrystalline silicon solar cells were fabricated from p-type Si wafer with n-type passivated emitters. Front Ag metal fingers, busbar and the Al/Ag back contact, and an Al back reflector were made by the screen-printing method. All the planar solar cells possessed a SiNx front layer as the antireflection coating with a thickness of 107 nm and refractive index (n) of 2.05 as measured by ellipsometry (using a J. A. Woollam M-2000XI). The raw solar cells were cut into 2×2 cm² and degreased by immersion into an ethanol bath for 1 min, then blown dry with a stream of nitrogen. The electroless deposition of Ag nanoparticles was accomplished by immersing the solar cells in an acidified aqueous solution of silver nitrate (10⁻³M AgNO₃ and 0.04 M HNO₃) for 5, 10 and 20 min. The silver-deposited solar cells were then removed from the metal solution and washed with copious amount of deionised water. The surface was subsequently blown dry with a stream of nitrogen.

Field emission scanning electron microscopic (FE-SEM) images of Ag nanoparticles deposited electrolessly via the galvanic displacement on the SiNₓ layer of Si solar cells as a function of the immersion time of (a) 5 min, (b) 10 min, and (c) 20 min, are shown in FIGS. 2C(a), 2C(b) and 2C(c) respectively. The electroless deposition leads to formation of predominately isolated Ag spherical particles randomly distributed on the surface. Both the particle density and average particle diameter increase with the deposition time. The average diameters of particles increased from 21 nm after 5 min of deposition to 110 nm after 20 min. The particle size distribution was calculated from the SEM images and depicted in the corresponding histograms in FIG. 2C. The sizes are 21±14.9, 52.5±15 and 110±39 nm for an immersion time of 5, 10 and 20 min, respectively. The corresponding surface coverage as a function of the immersion time was about 3%, 2.94%, and 11%. A broad distribution of nanoparticles sizes is represented by the standard deviation from 15 to 39 nm.

The chemical composition of the deposited Ag particles was confirmed by energy dispersive x-ray spectroscopy (EDX).

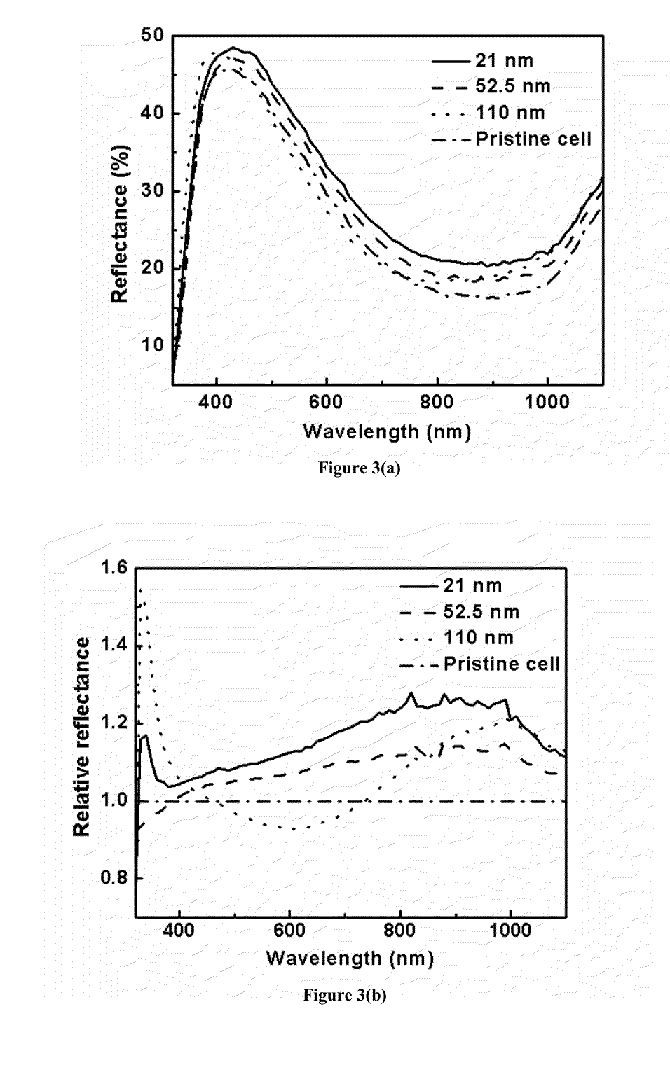

As shown in the reflectance measurements of planar Si solar cells before and after the deposition of Ag nanoparticles with mean diameters of 21, 52.5 and 110 nm in FIG. 3(a), the reflectance was reduced over broad wavelengths from 430 to 743 nm when Ag nanoparticles of mean diameter 110 nm were deposited on the front surface of the cells. A shown in the relative reflectance plots normalized to the solar cell without the Ag nanoparticles in FIG. 3(b), for the example solar cell with the 110-nm Ag nanoparticles, the reduction in reflectance was broad over the spectral range from 430 to 743 nm with an dip of 7.3% centred at 600 nm.

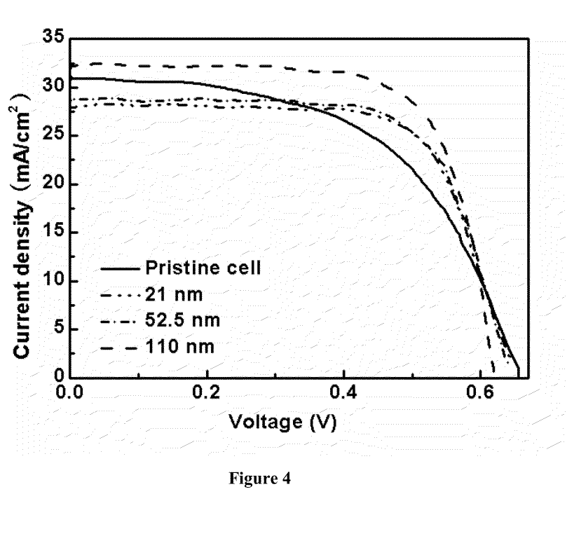

As shown in FIG. 4, the J-V characteristic graph of the example solar cells before and after electroless deposition of the Ag nanoparticles, the example nanoparticles improved the J_{sc} and the η in the solar cells. The largest enhancement was achieved by the example Ag nanoparticles of mean diameter 110 nm, giving 4.03% relative increase in the J_{sc}, and up to 35.23% relative increase in η.

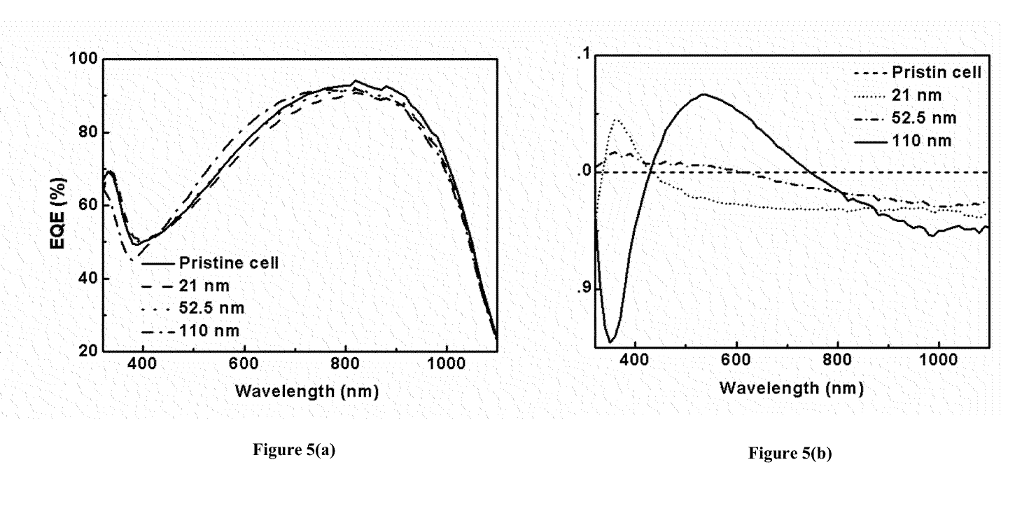

The external quantum efficiency (EQE) of the solar cells before and after the electroless deposition of the Ag nanoparticles is shown in FIGS. 5(a) and 5(b). An EQE measurement can be more relevant than an absorption measurement on the solar cells for determining the absorption enhancement in the cell because it can decouple the light absorption in the active layer from the parasitic absorption caused by the Ag nanoparticles. As shown in FIG. 5(b), in the relative enhancement compared to the pristine cell, the EQE for the cell coated with Ag nanoparticles of 110 nm was enhanced over the spectral range from 430 to 743 nm, with a pronounced peak centred at approximately 538 nm where the EQE was enhanced by 6.7%.

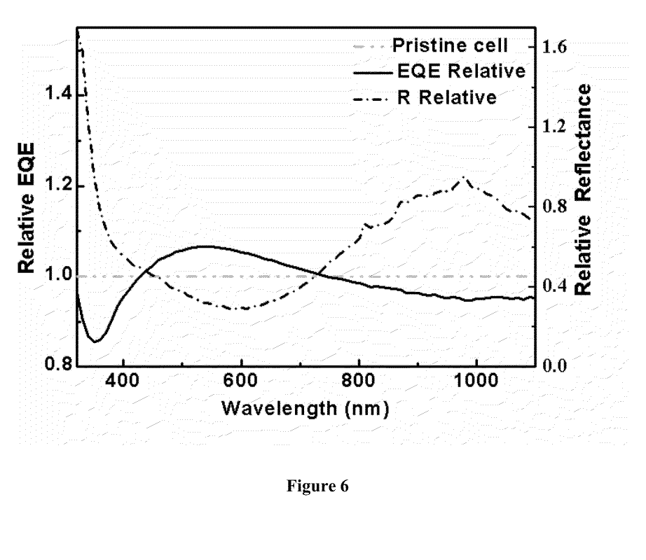

As shown in FIG. 6, the reflectance was correlated to the EQE, with an increase in reflectance resulting in a decrease in EQE at wavelengths below 400 nm. Furthermore, the large reduction of reflectance over the spectral range from 430 to 743 nm resulted in a substantial increase in EQE at the exact same spectral range.

After immersion in the electroless plating bath, the fingers of an example solar cell were plated with a shell of Ag (as shown in FIG. 7(a)), the front finger before the plating remained porous (as shown in FIG. 7(b)).

The thickness of the Ag shell depended on the immersion time: for a shorter time of about 5-10 min, only Ag nanoparticles were formed on the fingers; whereas for a longer time (more than about 20 min), a thicker continuous Ag shell was formed leading to the dramatic reduction of the series resistance, as shown in Table 1, where consistent decrease of the series resistance is evident for increased shell thickness.

As a result of the significantly reduced finger resistance, the example electroless plated solar cells exhibited a FF enhancement of up to 34.8% (as shown in Table 1), which contributed to the increase of 35.23% in the η, which is determined by η=FF V_{oc}/Pᵢₙ, where, Pᵢₙ is the input energy.

Table 1 shows a summary of J-V photovoltaic characteristics and photo-conversion efficiency enhancement for example planar silicon solar cells before and after electroless deposition of silver nanoparticles of average particle sizes of 21, 52.5, and 110 nm. The measurement conditions were at standard temperature and pressure (1000 w/m2, AM 1.5 G, 25 C).

TABLE 1

| | | J_{sc} | | Rₛ | | η Relative |
|---|---|---|---|---|---|---|
| Solar Cells | V_{oc} | (mA · | FF | (Ω · | η | Enhancement |
| (2 × 2 cm²) | (mV) | cm⁻²) | (%) | cm²) | (%) | (%) |
| Pristine | 655 | 31.05 | 56.408 | 8.9 | 11.24 | N/A |
| (as-received) | | | | | | |
| Ag-21 nm | 651.4 | 28.10 | 73.2362 | 2.42 | 13.41 | 19.7 |
| Ag-52.5 nm | 643.5 | 28.49 | 73.6014 | 1.99 | 13.5 | 20.2 |
| Ag-110 nm | 619 | 32.3 | 76.0332 | 1.4 | 15.2 | 35.2 |

### Dip-Coated Experimental Example

In an experimental example using the dip-coating method 200B, integration of 61-nm Au NPs onto an example multicrystalline Si solar cell led to:

an increase in energy conversion efficiency from 14.89% to 15.19%;

an increase of about 0.93% in short-circuit photocurrent density; and an increase of about 1.97% in energy conversion efficiency,

compared to the textured raw solar cells without Au NPs.

### Materials

In the experimental example using the dip-coating method 200B, commercially available hydrogen tetrachloroaurate trihydrate (HAuCl₄.3H₂O), sodium citrate and hydroxyamine were used without any further purification, and first distilled water was used for all solution preparation throughout all the experiments. All glassware was cleaned by soaking in aqua regia solution to ameliorate new particle nucleation (small particles).

### Preparation of Initial Au Seeds

The Au seeds were synthesized according to Frens' method. An aqueous solution of 500 ml of 1 mM M HAuCl₄ was heated to boiling with stirring; then 50 ml 1% (wt/v) aqueous sodium citrate was added all at once. The colour of the mixed solution changed from yellow to wine red in several minutes, indicating the formation of Au NPs. The boiling and stirring were continued for 15 min. Then the heat source was removed and the stirring was continued for additional 15 min. The seed solution was cooled to the room temperature and used directly for further experiments. This method produced Au NPs with a mean diameter of 14.7±1.56 nm according to the SEM and TEM images. The concentration of the Au seeds was estimated as ˜1.6×10¹² particles/ml. This initial Au seed batch was labelled as colloid “A”.

### Growth of Au NPs

A series of colloidal Au NPs with diameters in the range of 20-150 nm were prepared through the iterative seeding process. Six subsequent Au colloids (referred to as “A” to “G”) were prepared by taking six 300 ml conical flasks, hydroxylamine as reducing agent (0.375-1.25 ml) was mixed with deionized water (50-135 ml), then colloidal solution (15-55 ml) was added and finally 1% hydrogen tetrachloroaurate (HAuCl₄, 1 ml) was added under vigorous stirring at the room temperature. Addition of each reagent to the flask was conducted under vigorous stirring for 2 min. To prepare the colloid “C” with a specific particle size, colloid “B” was used as the seed; and to prepare colloid “D”, colloid “C” was used as the seed; etc.

With the above steps, the calculated diameters of the resulting Au particles were 18, 32, 41, 56, 110 and 149 nm for colloids “B” to “G”, respectively. Usually, Au colloids prepared by this method were stable for months under the proper storing conditions. Sedimentation was occasionally found, especially in the samples with larger particles, while the precipitate could be easily redispersed with a gentle shake; and the mean diameters of the Au NPs could be well preserved.

### Characterization of Colloidal Au NPs

The ultraviolet to visible to near-infrared (UV-VIS-NIR) absorption spectra of the Au colloidal solutions were measured with a spectrophotometer (Perkin Elmer, Lambda 1050), using a quartz cuvette with a 10-mm optical path in the wavelength range from 300 to 1100 nm (with deionised water as a reference). Scanning electron microscope (SEM, FEI Helios NanoLab 600i equipped with an energy dispersive X-ray unit) and transmission electron microscope (TEM, FEI Tecnai F20) images were used to characterize the morphology of the Au NPs. The Au colloid was dripped onto the Si substrate and carbon-coated copper grid and air-dried at the room temperature for the SEM and TEM imaging, respectively. The mean diameter and size distribution were measured from several SEM images by counting more than 100 NPs.

Integration of Au NPs with Si Solar Cells

Fifteen raw multicrystalline Si solar cells with initial efficiencies of around 15% were used to represent mainstream commercially available products. Before dipping, the raw solar cells were washed with ethanol and dried by N₂ gas.

Au NPs of size ranging from 50 to 150 nm were synthesized and integrated onto the front surface of these raw solar cells using a programmable dip coater (KSV company, model number: DS). The solar cells were mounted on a sample holder, vertically dipped into the colloidal Au solution, immersed for 4 min, and pulled out of the solution with a velocity of 30 mm/min, then dried in air at the room temperature. Commercial textured multicrystalline Si solar cells (Suntech Power Holdings Co., Ltd.) with metal contacts and ARC were employed. The ARC was made of SiN_{g} of 90 nm in thickness and had a refractive index n of 2.01 at 632.8 nm, as measured by an ellipsometer (J. A. Woollam M-2000XI). The Au NPs were integrated onto the top surface of all of the experimental raw solar cells.

Au NP colloidal solutions of concentrations 1.28×10¹¹, 1.72×10¹⁰, and 7×10⁹ NPs/ml for sizes 61, 107 and 146 nm, respectively, were used. The Au NPs surface coverage on solar cells was estimated from the SEM micrographs by calculating the particle density and the geometrical area of the particles.

Characterization of Solar Cells with and without Au NPs

The experimental solar cells with and without the Au NP were evaluated at 25° C. based on the illuminated current density versus voltage (J-V) characteristics, the EQE and the reflectance characterisation. The J-V curves were measured using a solar simulator (Oriel Sol 3A™ class AAA, model 94023A) with a Keithley 2400 source meter under the Air Mass 1.5 Global (AM 1.5G) illumination condition (100 mW/cm²) calibrated by a factory-calibrated Si module. The EQE was measured using the Bentham PVE300. The reflectance spectra of the samples were recorded using an integrating sphere of UV-VIS-NIR spectrophotometer (Perkin Elmer, Lambda 1050) for wavelengths ranging from 300 to 1200 nm.

FIG. 8 shows the SEM (a-f) and TEM (g, h, i) images of the synthesized Au NPs with diameters of (a, d, g) 61 nm; (b, e, h) 107 nm; and (c, f, i) 146 nm. The Au NPs were nearly spherical with uniform sizes and without any detectable by-products such as nanorods, triangles and small clusters. The measured mean diameters for Au NPs were 60.95±10, 107±13, and 146±17.7 nm, as estimated from the FE-SEM micrographs, which matched well with calculated values (56, 110 and 149 nm). The statistical analysis of the particles for all sizes revealed a size distribution with a mean standard deviation a ranging from 10 to 17 nm, indicating that NPs had a homogeneous size distribution as depicted in the histograms in FIGS. 8(j) to 8(l). The surfaces were substantially smooth, indicating that the Au NPs were single particles rather than agglomerations of smaller units.

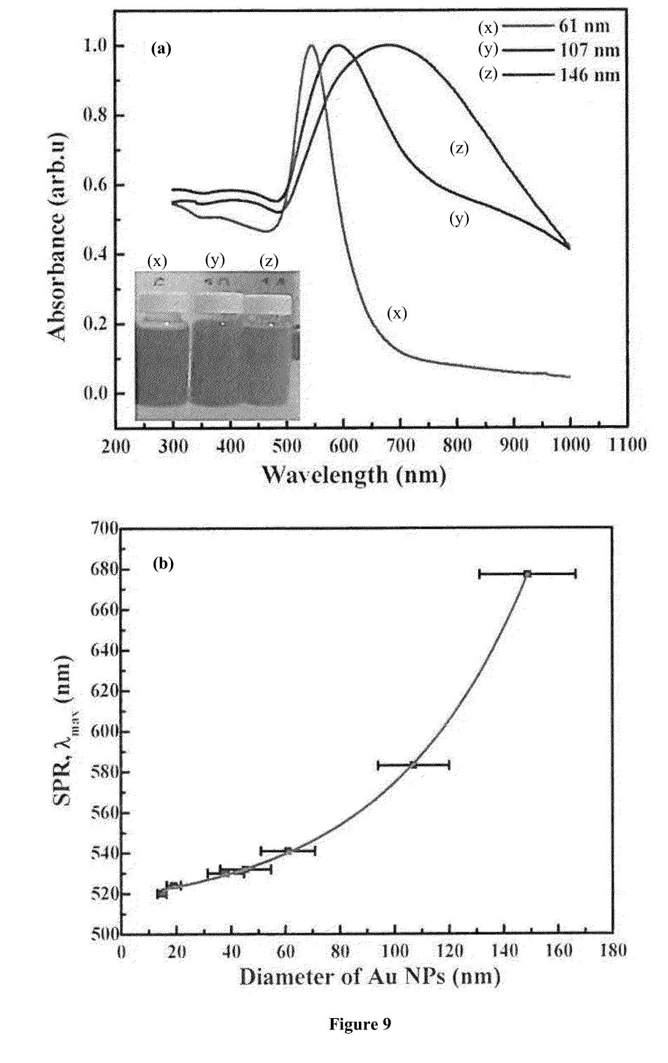

The measured absorption spectra measured for the 61-, 107- and 146-nm diameter Au colloidal NPs suspended in aqueous solution confirmed the existence of particle-size dependent surface plasmon resonances (SPRs), as shown in FIG. 9(a). Maxima in the absorption spectra were evident at wavelengths corresponding to the surface plasmon excitations in the Au NPs, and the peak red-shifted and broadened with increasing particle diameter. In FIG. 9(b) the dependence of the plasmon resonance peak position is plotted versus the particle diameter, which shows that the peak position of the SPR increased from 541 to 682 nm with increasing particle size from 61 to 146 nm.

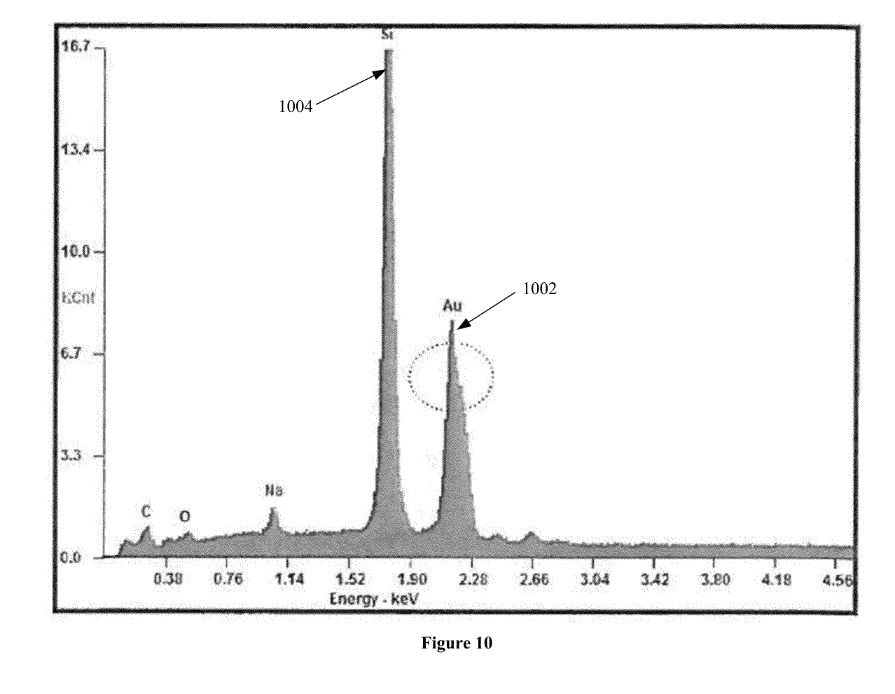

The presence of an Au peak was evident in a measured EDX spectra, as shown in FIG. 10.

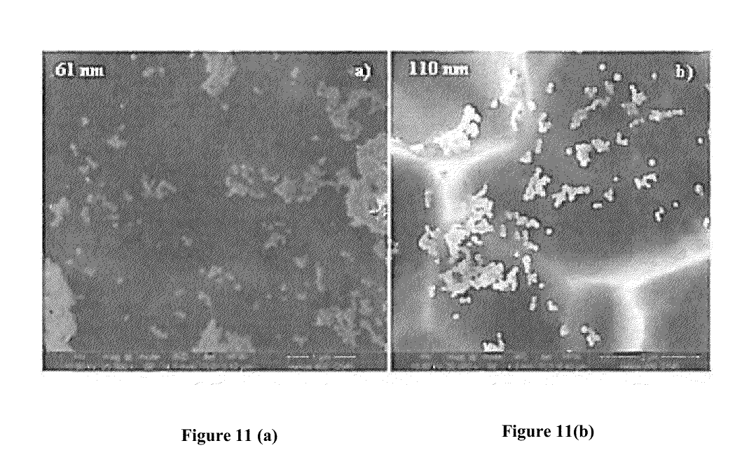

The deposition of Au NPs by the dip coating method can result in predominantly isolated NPs with the presence of few clustered NPs, as shown in FIG. 11(a) for 61-nm particles and FIG. 11(b) for 107-nm particles. The clustered NPs may have been formed when the nanospheres in the drying layer were attracted to each other by the capillary forces.

The distribution of Au NPs was substantially uniform over larger areas of the surface.

The surface coverage density was about 12% (e.g., as deduced from the SEM micrographs).

Photovoltaic Characteristics of Solar Cells with and without Au NPs

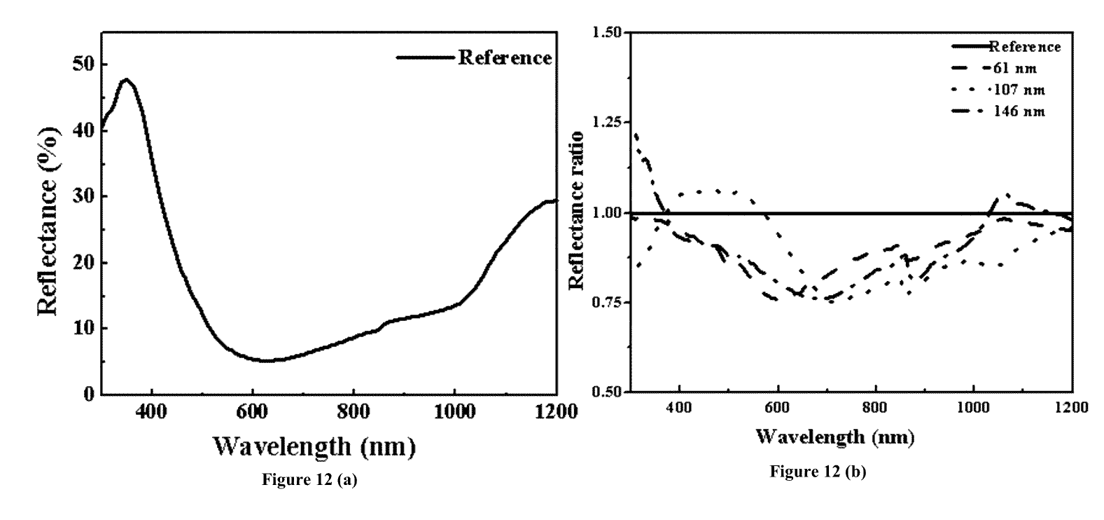

The reflection spectrum of the example raw solar cell without NPs is shown in FIG. 12(a). The reflectance ratios of the example cells integrated with Au NPs of mean diameters 61, 107 and 146 nm relative to the same raw cell prior to the integration are shown in FIG. 12(b). The reflectance was substantially reduced in the UV and NIR regions for the cells with Au NPs of mean diameter 61 nm. The reduction in reflectance was broad over the spectral range from 300 to 1200 nm with a sharp reduction peak by 25% centred at a wavelength of approximately 600 nm due to the SPR of the Au NPs, which exhibits λ_{SPR} close to 600 nm (as shown in FIG. 9(b)). On the other hand, for Au particles of size 107 and 146 nm, the reduction in reflectance was not broad over a large spectral range from 300-1200 nm. For Au NPs of diameter 107 nm, the reflectance reduced at longer wavelengths from 700-1200 nm, while at shorter wavelengths from 400 to 650 nm it slightly increased. The reflectance decreased at the wavelengths from 400 to 1000 nm but increased at λ<400 nm and λ>1000 nm for solar cells incorporated Au NPs of mean diameter 146 nm. The Au NPs of diameter 61 nm that reduced the cell reflectance across the entire solar spectrum achieved the highest enhancement in the solar cell performance in this example.

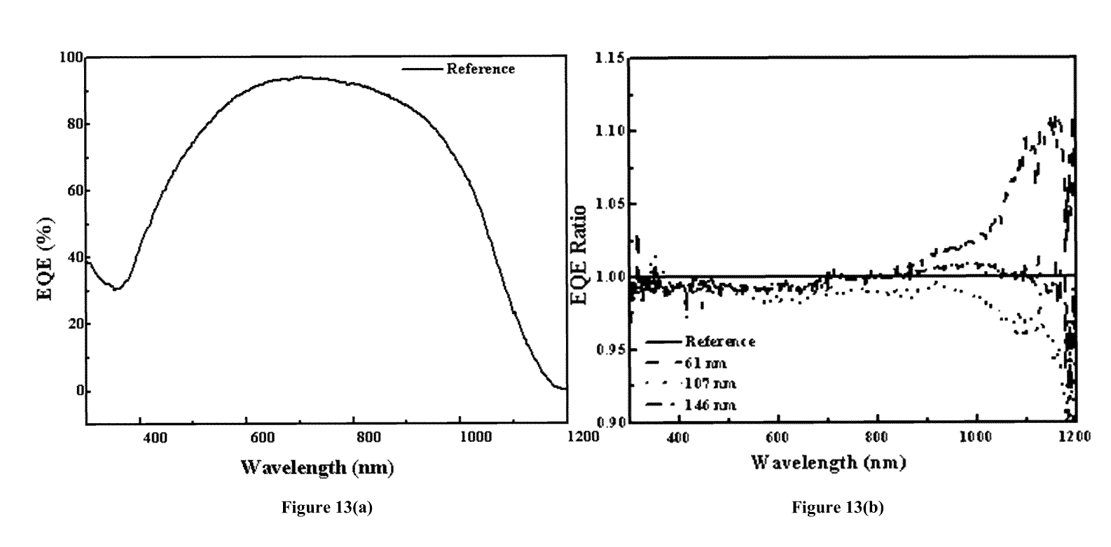

EQE of solar cells before integration of Au NPs—as well as EQE ratio of cells integrated with Au NPs of mean diameters 61, 107 and 146 nm relative to the same cell prior to integration—are depicted in FIGS. 13(a) and 13(b), respectively. For cells with 61-nm Au NPs, as shown in FIG. 13(b), the EQE slightly reduced at λ≦700 nm, and significantly increased at longer wavelengths, 800<λ≦1200 nm. The EQE was enhanced by more than 11% at wavelength of 1150 nm, thus the response of the example coated solar cells was improved in the NIR region.

Table 2, below, presents the IV parameters of the example dip-coated solar cells before and after integration with Au NP of diameters 61, 107, and 146 nm. The highest enhancement in energy conversion efficiency was 1.97% for example dip-coated cells integrated with Au NPs of mean diameter 61 nm, and both short-circuit photocurrent density (J_{sc}) and fill factor (FF) were enhanced by 0.93%. The solar cells integrated with Au NPs of diameter 61 nm showed an increased in all I-V parameters (J_{sc}, V_{oc}, FF and energy conversion efficiency (η) and also enhancement in J_{sc}.

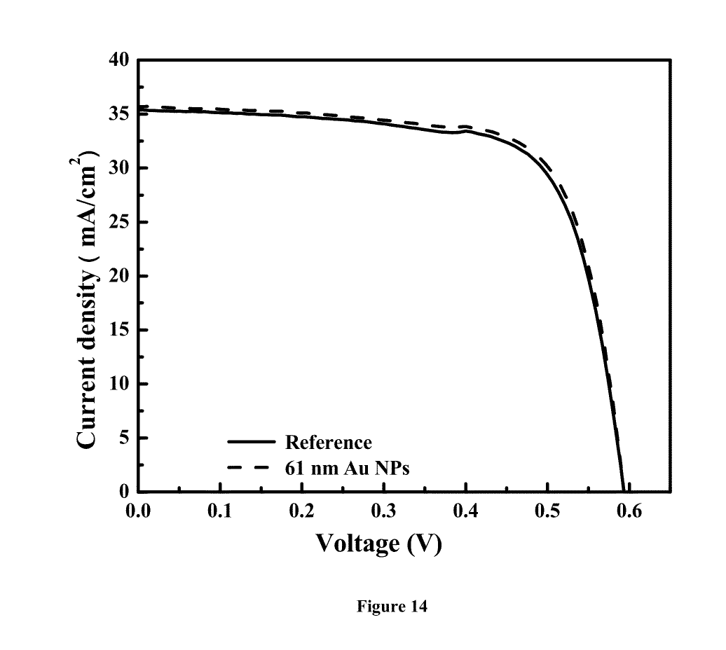

FIG. 14 shows the photocurrent density—voltage (J-V) characteristic of the example dip-coated solar cells at maximum enhancement with 61-nm Au NPs. The performance of the cell without Au NPs is also shown, for comparison. J_{sc}, V_{oc}, FF, and η for the cell integrated with Au NPs are 35.72 mA/cm², 593.32 mV, 71.67%, 15.19% and, for the reference cell are 35.39 mA/cm², 592.75 mV, 71.01, and 14.89%, respectively. The energy conversion efficiency was improved from 14.89 to 15.19%; thus, the maximum enhancement in energy conversion efficiency was 1.97% for the example dip-coated cell integrated with Au NPs of mean diameter 61 nm. All the I-V parameters of the example dip-coated solar cells before and after integration with the Au NPs of diameters 61, 107, 146 nm are summarized in Table 2 below.

TABLE 2

| | | | | | η Relative |
|---|---|---|---|---|---|
| Solar | V_{oc} | J_{sc} | FF | η | Enhancement |
| Cells | (mV) | (mA · cm⁻²) | (%) | (%) | (%) |
| Without | 592.7505 | 35.38869 | 71.0103 | 14.8956 | — |
| NPs | | | | | |
| With | 593.319 | 35.71664 | 71.6726 | 15.1884 | 1.965681 |
| 61 nm | | | | | |
| Au NPS | | | | | |
| Without | 588.5267 | 35.42909 | 72.2714 | 15.0693 | — |
| NPs | | | | | |
| With | 589.7816 | 35.58772 | 72.0482 | 15.1222 | 0.351045 |
| 107 nm | | | | | |
| Au NPS | | | | | |
| Without | 582.612 | 34.35584 | 73.7568 | 14.7632 | — |
| NPs | | | | | |
| With | 583.9779 | 34.6235 | 73.6132 | 14.8841 | 0.818928 |
| 146 nm | | | | | |
| Au NPS | | | | | |

### Interpretation

Many modifications will be apparent to those skilled in the art without departing from the scope of the present invention as hereinbefore described with reference to the accompanying drawings.

The reference in this specification to any prior publication (or information derived from it), or to any matter which is known, is not, and should not be taken as an acknowledgment or admission or any form of suggestion that the prior publication (or information derived from it) or known matter forms part of the common general knowledge in the field of endeavour to which this specification relates.

1. A solar cell product including:
a bulk semiconductor substrate having one or more solar cells formed therein; and
nanoscale particles distributed over a surface of the solar cells to scatter sunlight forward into the solar cells and thereby enhance the efficiency of the solar cells.

2. The solar cell product of claim 1, wherein the particles are deposited from a suspension of the particles.

3. The solar cell product of claim 1, wherein the particles are deposited from reduction of ions in solution.

4. The solar cell product of claim 1, wherein the particles have diameters ranging from about 10 nanometres (nm) to about 100 nm.

5. The solar cell product of claim 1, wherein the particles are spherical.

6. The solar cell product of claim 1, wherein the bulk semiconductor substrate is multicrystalline or monocrystalline.

7. The solar cell product of claim 1, wherein the particles are deposited with a surface coverage density of about 0.5% to about 10%.

8. The solar cell product of claim 1 including:
conductive fingers or conductors for conducting electricity generated from the sunlight; and
conductive coatings deposited from the solution on the conductive fingers or conductors for conducting the electricity.

9. A method of manufacturing a solar cell including:
receiving a bulk semiconductor substrate having solar cells formed therein; and
depositing nanoscale particles on a surface of the solar cells to scatter light forward into the solar cells.

10. The method of claim 9, wherein the step includes depositing conductive coatings on conductive fingers on the solar cell.

11. The method of claim 9, wherein the particles are deposited by electroless deposition from an ionic solution.

12. The method of claim 9, wherein the particles are deposited by dipping the solar cell into a suspension of the particles.

13. A solar cell including nanoparticles, synthesised using a wet chemical method, on a front surface of the cell.

14. The solar cell of claim 13, wherein the wet chemical method includes depositing the nanoparticles from a solution including a colloidal suspension of the nanoparticles.

15. The solar cell of claim 14, wherein preparing the colloidal suspension includes depositing material on seed nanoparticles to grow the nanoparticles with selected sizes for enhancing absorption of sunlight.

16. The solar cell of claim 15, wherein the selected sizes include diameters from 20 nm to 300 nm.

17. The solar cell of claim 13, wherein the nanoparticles are deposited on an anti-reflection coating of the surface

18. The solar cell of claim 13, wherein the nanoparticles are deposited from solution onto the front surface of the cell.

19. The solar cell of claim 18 wherein a conductive coating is deposited from the solution onto conductors of the solar cell.

20. The solar cell of claim 13, wherein the nanoparticles are synthesised with selected sizes for enhancing absorption of sunlight with wavelengths from 800 nm to 1200 nm.
